(19) United States
(12) Patent Application Publication
(10) Pub. No.: US 2010/0327425 A1
(43) Pub. Date: Dec. 30, 2010

(54) FLAT CHIP PACKAGE AND FABRICATION METHOD THEREOF

(75) Inventor: CHING-YAO FU, Tu-Cheng (TW)

Correspondence Address: Altis Law Group, Inc.;ATTN: Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/577,251

(22) Filed: Oct. 12, 2009

(30) Foreign Application Priority Data
Jun. 30, 2009 (CN) 200910108561.2

(51) Int. Cl. H01L 23/49; H01L 21/50

(52) U.S. Cl. 257/692; 438/124; 257/E21.499; 257/E23.024

(57) ABSTRACT

A flat chip package comprises an encapsulation body, a plurality of connecting fingers, a plurality of conductive lines, a chip, a plurality of bond wires and an insulation layer. The conductive lines, the chip, and the bond wires are encapsulated in the encapsulation body. The connecting fingers comprise a ground finger, a power finger and at least one signal finger. One side of the connecting fingers adheres to a surface of the encapsulation body, the other side of the connecting fingers is left exposed. The conductive lines comprise a ground line connected to the ground finger, and a power line connected to the power finger. The chip comprises a ground pin, a power pin and at least one signal pin. The bond wires connect the connecting fingers, the conductive lines and the chip. The insulation layer is printed on the surface of the encapsulation body except for the connecting fingers.

### BACKGROUND

1. Technical Field

Embodiments of the present disclosure relate to semiconductor packages, and particularly to a flat chip package and fabrication method thereof.

2. Description of Related Art

Often, portable electronic devices with multiple functions comprise either a plurality of chips or a multifunctional chip integrating a plurality of function modules. As miniaturization is an inevitable tendency of the portable electronic devices, size of the chips need be miniaturized correspondingly to meet market demands.

### BRIEF DESCRIPTION OF THE DRAWINGS

Many aspects of the embodiments can be better understood with references to the following drawings, wherein like numerals depict like parts, and wherein:

FIG. 1 is a plan view of a flat chip package of one embodiment of the present disclosure;

FIG. 2 is a side cross-sectional view of the flat chip package of FIG. 1, taken on a line 1A-1A through FIG. 1, in accordance with one embodiment of the present disclosure; and

FIG. 3 is a flowchart of a fabrication method of the flat chip package in accordance with one embodiment of the present disclosure.

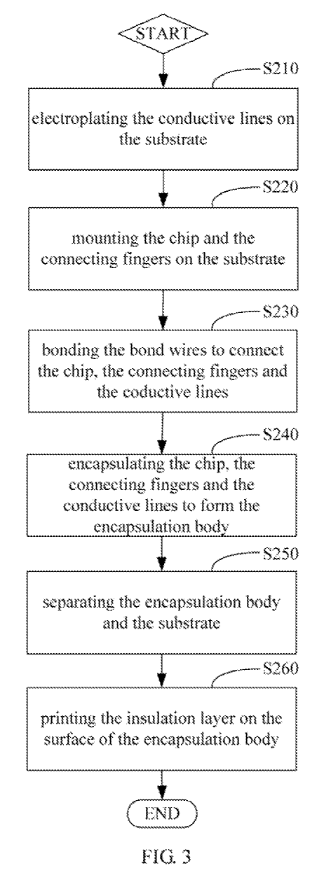

### DETAILED DESCRIPTION

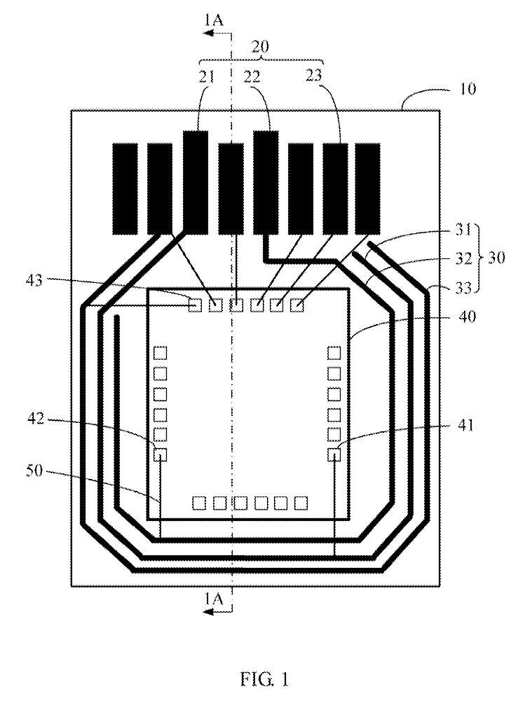

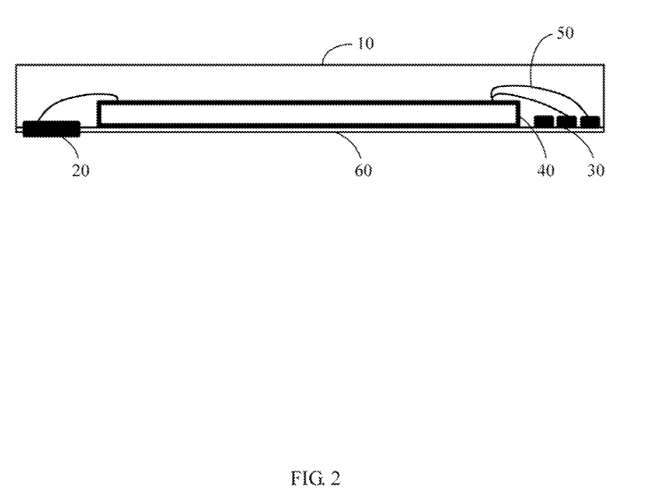

FIGS. 1 and 2 illustrate a flat chip package of one embodiment of the present disclosure. The flat chip package comprises an encapsulation body 10, a plurality of connecting fingers 20, a plurality of conductive lines 30, a chip 40, a plurality of bond wires 50 and an insulation layer 60.

The encapsulation body 10 encapsulates the conductive lines 30, the chip 40 and the bond wires 50. In one embodiment, the encapsulation body 10 may be formed from plastic materials, such as epoxy, polyphenylene sulfide, RYTON, for example, by a molding process.

The connecting fingers 20 comprise a ground finger 21, a power finger 22 and at least one signal finger 23. In one embodiment, one side of the connecting fingers 20 adheres to the encapsulation body 10, the other side of the connecting fingers is left exposed (refer to FIG. 2). It should be understood that “exposed” is defined as not having contact with the encapsulation body 10.

The conductive lines 30 comprise a ground line 31 connected to the ground finger 21 of the connecting fingers 20, and a power line 32 connected to the power finger 22 of the connecting fingers 20. In alternative embodiments, the conductive lines 30 further comprise at least one signal line 33 connected to the at least one signal finger 23 of the connecting fingers 23 correspondingly. The conductive lines 30 may be formed from conductive materials, such as copper, aluminum, gold, for example, by an electroplating process.

The chip 40 is encapsulated in the encapsulation body 10, and comprises a ground pin 41, a power pin 42 and at least one signal pin 43. The ground pin 41 of the chip 40 is connected to the ground line 31 of the conductive lines 30 via one of the bond wires 50. The power pin 42 of the chip 40 is connected to the power line 32 of the conductive lines 30 via another one of the bond wires 50. The at least one signal pin 43 of the chip 40 is connected to the at least one signal finger 23 of the connecting fingers 20 via at least one of the bond wires 50. In alternative embodiments, the at least one signal pin 43 of the chip 40 is connected to the at least one signal line 33 of the conductive lines 30 via at least one of the bond wires 50, and the at least one signal line 33 of the conductive lines 30 is connected to the at least one signal finger 23 of the connecting fingers 20.

The insulation layer 60 substantially covers the surface of the encapsulation body 10 except for the connecting fingers 20. In one embodiment, the insulation layer 60 may be formed from insulation materials, such as solder mask and solder resist, by a printing process.

Referring to FIG. 2, a flowchart of a fabrication method of the flat chip package of one embodiment of the present disclosure is shown. In one embodiment, the fabrication method of the flat chip package structure comprises a plurality of steps as follows.

In step 210, the conductive lines 30 are electroplated on a substrate. The conductive lines 30 are formed with conductive materials, such as copper, aluminum, gold, for example. The substrate is employed as a supporting board in the fabrication of the flat chip package, and formed from materials operable to be easily separated from the conductive lines 30. In one embodiment, the conductive lines 30 comprise a ground line 31 and a power line 32. In alternative embodiments, the conductive lines 30 further comprise at least one signal line 33.

In step 220, the connecting fingers 20 and the chip 40 are mounted on the substrate. The connecting fingers 20 comprise a ground finger 21, a power finger 22 and at least one signal finger 23. The chip 40 comprises a ground pin 41, a power pin 42 and at least one signal pin 43.

In step 230, the bond wires 50 are bonded to connect the connecting fingers 20, the conductive lines 30 and the chip 40. In one embodiment, the ground pin 41 of the chip 40 is connected to the ground line 31 of the conductive lines 30 via one of the bond wires 50. The power pin 42 of the chip 40 is connected to the power line 32 of the conductive lines 30 via another of the bond wires 50. The at least one signal pin 43 of the chip 40 is connected to the at least one signal finger 23 of the connecting fingers 20 via at least one of the bond wires 50 correspondingly. In alternative embodiments, the at least one signal pin 43 is connected to the at least one signal line 33 of the conductive lines 30 via at least one of the bond wires 50, and the at least one signal line 33 of the conductive lines 30 is connected to the at least one signal finger 23 of the connecting fingers 20 correspondingly.

In step 240, the connecting fingers 20, the conductive lines 30, the chip 40 and the bond wires 50 are molded in an encapsulation body 10. As mentioned above, the encapsulation body 10 may be formed form plastic materials, such as epoxy, polyphenylene sulfide, RYTON, for example.

In step 250, the encapsulation body 10 is separated from the substrate. A surface of the encapsulation body 10 originally formed on the substrate exposes the connecting fingers 20, the conductive lines 30 and the chip 40.

In step 260, the insulation layer 60 is printed to substantially cover the conductive lines 30 and the chip 40, and prevent exposure of the conductive line 30 and the chip 40 from the surface of the encapsulation body 10. The insulation layer 60 is formed from insulation materials, such as solder mask and resist.

It is apparent that embodiments of the present disclosure provide a flat chip package and fabrication method thereof operable to utilize thin insulation layers and electroplating conductive lines rather than print circuit board substrates and electric lines thereon, which leads to flat chip package structure, and correspondingly lower fabrication cost.

While the present disclosure has been described in combination with embodiments thereof, it is evident that many alternatives, modifications, and variations will be apparent to those skilled in the art in light of the foregoing description. Accordingly, it is intended to embrace all such alternatives, modifications, and variations as fall within the spirit and scope of the appended claims.

What is claimed is:

1. A flat chip package, comprising:
an encapsulation body;
a plurality of connecting fingers comprising a ground finger, a power finger and at least one signal finger, wherein one side of the plurality of connecting fingers adheres to the encapsulation body, the other side of the plurality of connecting fingers is left exposed;
a plurality of conductive lines encapsulated in the encapsulation body, comprising a ground line connected to the ground finger of the plurality of connecting fingers and a power line connected to the power finger of the plurality of connecting fingers;
a chip encapsulated in the encapsulation body and connected to the plurality of connecting fingers and the plurality of conductive lines via a plurality of bond wires, the chip comprising a ground pin, a power pin and at least one signal pin; and
an insulation layer substantially covering the surface of the encapsulation body except for the plurality of connecting fingers.

2. The flat chip package as claimed in claim 1, wherein the insulation layer is formed from insulation materials by a printing process.

3. The flat chip package as claimed in claim 1, wherein the ground pin of the chip is connected to the ground line of the plurality of conductive lines, the power pin of the chip is connected to the power line of the plurality of conductive lines, and the at least one signal pin of the chip is connected to the at least one signal finger of the plurality of connecting finger.

4. The flat chip package as claimed in claim 1, wherein the plurality of conductive lines further comprises at least one signal line connected to the at least one signal finger of the plurality of connecting fingers.

5. The flat chip package as claimed in claim 4, wherein the ground pin of the chip is connected to the ground line of the plurality of conductive lines, the power pin of the chip is connected to the power line of the plurality of conductive lines, and the at least one signal pin of the chip is connected to the at least one signal line of the plurality of conductive lines.

6. A fabrication method of a flat chip package, comprising:
electroplating a plurality of conductive lines comprising a ground line and a power line on a substrate of the flat chip package;
mounting a chip and a plurality of connecting fingers on the substrate, wherein the plurality of connecting fingers comprises a ground finger, a power finger and at least one signal finger, and the chip comprises a ground pin, a power pin and at least one signal pin;
bonding a plurality of bond wires to connect the chip, the plurality of conductive lines and the plurality of connecting fingers correspondingly;
encapsulating the chip, the plurality of conductive lines and the plurality of connecting fingers to form an encapsulation body;
separating the encapsulation body from the substrate, wherein a surface of the encapsulation body originally formed on the substrate exposes the plurality of conductive lines, the chip and the plurality of connecting fingers;
printing insulation materials on the surface of the encapsulation body to substantially cover the plurality of conductive lines and the chip to form an insulation layer.

7. The fabrication method as claimed in claim 6, wherein the ground pin of the chip is connected to the ground line of the plurality of conductive lines, the power pin of the chip is connected to the power line of the plurality of conductive lines, and the at least one signal pin of the chip is connected to the at least one signal finger of the plurality of connecting fingers.

8. The fabrication method as claimed in claim 6, wherein the plurality of conductive lines further comprises at least one signal line connected to the at least one signal finger of the plurality of connecting fingers.

9. The fabrication method as claimed in claim 8, wherein the ground pin of the chip is connected to the ground line of the plurality of conductive lines, the power pin of the chip is connected to the power line of the plurality of conductive lines, and the at least one signal pin of the chip is connected to the at least one signal line of the plurality of conductive lines.
